(19) United States
(12) Patent Application Publication
(10) Pub. No.: US 2021/0118972 A1
(43) Pub. Date: Apr. 22, 2021

(54) ORGANIC ELECTROLUMINESCENT DISPLAY SUBSTRATE, METHOD FOR FABRICATING THE SAME, AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Fuwei ZOU, Beijing (CN); Shiyang XU, Beijing (CN); Yue WEI, Beijing (CN)

(21) Appl. No.: 17/072,364

(22) Filed: Oct. 16, 2020

(30) Foreign Application Priority Data
Oct. 17, 2019 (CN) 201910990937.0

(51) Int. Cl. H01L 27/32; H01L 51/56; H01L 51/52

(52) U.S. Cl. CPC H01L 27/3276; H01L 2227/323; H01L 51/5209; H01L 51/56

(57) ABSTRACT

The present disclosure provides an organic electroluminescent display substrate, a method for fabricating the same, and a display device. The organic electroluminescent display substrate includes: a substrate; a circuit element on the substrate; a first insulating layer on a side of the circuit element away from the substrate and having at least one groove; a first conductive portion at least partially filled in the at least one groove and at least partially electrically coupled to the circuit element; a second insulating layer on a side of the first conductive portion away from the circuit element and covering the first insulating layer and the first conductive portion; and a light-emitting element on a side of the second insulating layer away from the first conductive portion.

### CROSS-REFERENCE TO RELATED APPLICATION

This application claims priority to Chinese Patent Application No. 201910990937.0, filed on Oct. 17, 2019 to China National Intellectual Property Administration, the contents of which are incorporated herein by reference in the entirety.

### TECHNICAL FIELD

The present application relates to the field of display technology, and particularly relates to an organic electroluminescent display substrate, a method for fabricating the same, and a display device.

### BACKGROUND

Organic light-emitting diode (OLED) display is a third-generation display technology following liquid crystal display (LCD) display. The OLED display technology has advantages of self-luminescence, wide viewing angle, almost infinite contrast, low power consumption, extremely high response speed and the like, and has very good market prospect.

At present, in order to improve the display effect of an OLED display product, the OLED display product generally adopts a two-layer circuit design structure, and a light-emitting element is formed above the two-layer circuit structure. One layer of circuit structure close to the light-emitting element may form a convex surface, and the convex surface may cause unevenness of a surface of an insulating layer over the circuit structure and thus unevenness of a surface of an anode of the light-emitting element on the insulating layer, thereby resulting in color cast of a display picture of an OLED display product, and having an adverse impact on the display effect.

### SUMMARY

In one aspect, embodiments of the present disclosure provide an organic electroluminescent display substrate including: a substrate; a circuit element on the substrate; a first insulating layer on a side of the circuit element away from the substrate and having at least one groove recessed from a surface of the first insulating layer away from the substrate, the at least one groove having a depth less than a thickness of the first insulating layer at a position where the at least one groove is located; a first conductive portion at least partially filled in the at least one groove and at least partially electrically coupled to the circuit element; a second insulating layer on a side of the first conductive portion away from the circuit element and covering the first insulating layer and the first conductive portion; and a light-emitting element on a side of the second insulating layer away from the first conductive portion.

In some embodiments, a surface of the first conductive portion away from the circuit element is flush with a surface of the first insulating layer away from the circuit element, and the second insulating layer is in direct contact with the surface of the first conductive portion and the surface of the first insulating layer away from the circuit element.

In some embodiments, the circuit element includes a transistor having a first electrode, a second electrode, and a control electrode, the at least one groove includes a first groove and a second groove separated from each other, the first conductive portion includes a conductive electrode at least partially filled in the first groove and a conductive line at least partially filled in the second groove, and the conductive electrode is electrically coupled to at least one of the first electrode and the second electrode of the transistor through a via hole in the first insulating layer.

In some embodiments, an orthographic projection of the first conductive portion on the substrate at least partially overlaps with an orthographic projection of the light-emitting element on the substrate.

In some embodiments, the orthogonal projection of the first conductive portion on the substrate falls within the orthogonal projection of the light-emitting element on the substrate.

In some embodiments, an orthographic projection of the conductive line on the substrate at least partially overlaps with an orthographic projection of the light-emitting element on the substrate.

In some embodiments, the orthographic projection of the conductive line on the substrate is within the orthographic projection of the light-emitting element on the substrate.

In some embodiments, the organic electroluminescent display substrate further includes a gate insulating layer and an interlayer dielectric layer sequentially stacked on the substrate. At least a portion of the control electrode of the transistor is in the gate insulating layer, each of the first and second electrodes of the transistor has a first portion penetrating through the gate insulating layer and the interlayer dielectric layer and a second portion on a surface of the interlayer dielectric layer away from the gate insulating layer, and the first insulating layer is in direct contact with the surface of the interlayer dielectric layer and the second portion of each of the first and second electrodes of the transistor.

In some embodiments, the organic electroluminescent display substrate further includes a signal line including at least a portion on a surface of the interlayer dielectric layer away from the gate insulating layer, and the first insulating layer is in direct contact with the signal line.

In some embodiments, an orthographic projection of the conductive line on the substrate at least partially overlaps with an orthographic projection of the signal line on the substrate.

In some embodiments, the conductive electrode and the conductive line have a same material and are in a same layer.

In some embodiments, in a cross-sectional view taken along a line perpendicular to an extending direction of the conductive line, the conductive electrode and the conductive line have different cross-sectional shapes.

In some embodiments, the first insulating layer and the second insulating layer are organic material layers.

In some embodiments, the first conductive portion is completely filled in the at least one groove.

In another aspect, embodiments of the present disclosure provide a display device including the organic electroluminescent display substrate described above.

In another aspect, embodiments of the present disclosure provide a method for fabricating an organic electroluminescent display substrate, including: forming a circuit element on a substrate; forming a first insulating layer on a side of the circuit element away from the substrate, the first insulating layer having at least one groove recessed from a surface of the first insulating layer away from the substrate and having a depth less than a thickness of the first insulating layer at a position where the at least one groove is located; forming a first conductive portion at least partially filling in the at least one groove and at least partially electrically coupled to the circuit element; forming a second insulating layer on a side of the first conductive portion away from the circuit element, the second insulating layer covering the first insulating layer and the first conductive portion; and forming a light-emitting element on a side of the second insulating layer away from the first conductive portion.

In some embodiments, the forming of the first insulating layer includes: coating a first insulating layer film on the substrate; patterning the first insulating layer film using a half-tone exposure process to form the first insulating layer having the at least one groove.

In some embodiments, the forming of the first conductive portion includes: filling the first conductive portion in the at least one groove.

In some embodiments, the first conductive portion is completely filled in the at least one groove.

In some embodiments, the circuit element includes a transistor having a first electrode, a second electrode, and a control electrode, the at least one groove includes a first groove and a second groove separated from each other, the first conductive portion includes a conductive electrode at least partially filled in the first groove and a conductive line at least partially filled in the second groove, the conductive electrode is electrically coupled with at least one of the first electrode and the second electrode of the transistor through a via hole in the first insulating layer.

### BRIEF DESCRIPTION OF DRAWINGS

FIG. 1 is a schematic cross-sectional view of an organic electroluminescent display substrate according to an embodiment of the present disclosure;

FIG. 2 is a schematic cross-sectional view of an organic electroluminescent display substrate in which a first insulating layer has been formed, according to an embodiment of the present disclosure;

FIG. 3 is a schematic cross-sectional view of an organic electroluminescent display substrate in which a first conductive portion has been formed, according to an embodiment of the present disclosure;

FIG. 4 is a schematic cross-sectional view of an organic electroluminescent display substrate according to an embodiment of the present disclosure; and

FIG. 5 is an exemplary partial plan view of an organic electroluminescent display substrate according to an embodiment of the present disclosure.

### DETAILED DESCRIPTION

To make those skilled in the art better understand the technical solutions of the present disclosure, an organic electroluminescent display substrate, a method for fabricating the same, and a display device according to the present disclosure will be further described in detail below in conjunction with the accompanying drawings and specific embodiments.

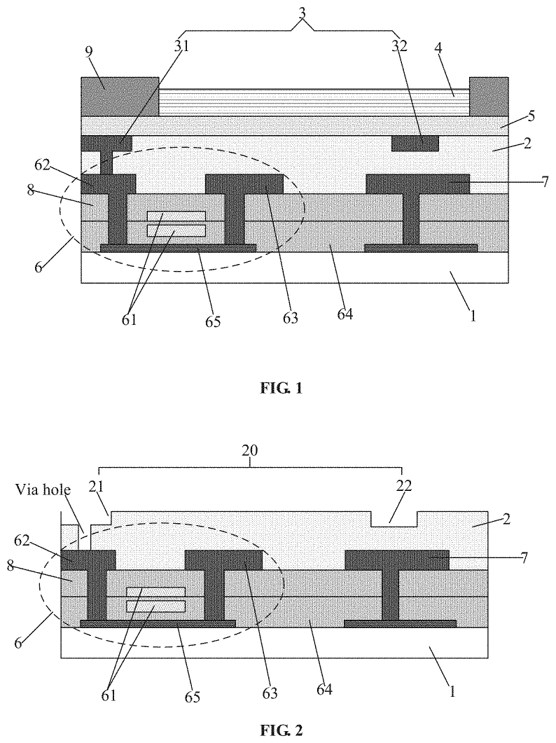

In one aspect, embodiments of the present disclosure provide an organic electroluminescent display substrate. As shown in FIG. 1, the organic electroluminescent display substrate includes: a substrate 1; a circuit element (e.g., a transistor 6 in FIG. 1) on substrate 1; a first insulating layer 2 on a side of the circuit element away from the substrate 1 and having at least one groove 20 (see FIG. 2) recessed from a surface (e.g., an upper surface in the drawings) of the first insulating layer away from the substrate 1, the at least one groove having a depth less than a thickness of the first insulating layer 2 at a position where the groove is located; a first conductive portion 3 at least partially filled in the at least one groove 20 and at least partially electrically coupled to the circuit element; a second insulating layer 5 on a side of the first conductive portion 3 away from the circuit element and covering the first insulating layer 2 and the first conductive portion 3; and a light-emitting element 4 on a side of the second insulating layer 5 away from the first conductive portion 3.

The first insulating layer 2 and the second insulating layer 5 may serve as a first planarization layer and a second planarization layer, respectively.

In the case where the first conductive portion is formed in the second insulating layer, an upper surface of the second insulating layer may be uneven, for example, an upper surface of a portion of the second insulating layer in which the first conductive portion is disposed protrudes slightly, which may cause unevenness of the light-emitting element formed on the second insulating layer. However, in the embodiments of the present disclosure, by at least partially filling the first conductive portion 3 in the groove 20 formed in the first insulating layer (such first insulating layer and first conductive portion may be referred to as an embedded structure), the unevenness of the surface (for example, the upper surface of the second insulating layer 5 in FIG. 1) where the light-emitting element 4 is located can be alleviated or prevented, so that the display color cast of the organic electroluminescent display substrate due to the unevenness of the surface where the light-emitting element 4 is located can be alleviated or prevented, and the display effect of the organic electroluminescent display substrate can be improved.

It should be noted that, one pair of the first insulating layer 2 and the first conductive portion 3 with the embedded structure may be disposed between the light-emitting element 4 (or the second insulating layer 5) and the substrate 1; alternatively, a plurality of pairs of the first insulating layer 2 and the first conductive portion 3 with the embedded structure may be disposed between the light-emitting element 4 (or the second insulating layer 5) and the substrate 1, which may alleviate or prevent the unevenness of the surface where the light-emitting element 4 is located, thereby alleviating or preventing the display color cast of the organic electroluminescent display substrate caused by the unevenness of the surface where the light-emitting element 4 is located.

Note that FIG. 5 shows an example of a partial plan view of an organic electroluminescent display substrate according to an embodiment of the present disclosure, but the plan view of the organic electroluminescent display substrate according to an embodiment of the present disclosure is not limited thereto.

In some embodiments, the first conductive portion is completely filled in the groove 20.

In some embodiments, a surface of the first conductive portion 3 away from the circuit element is flush with a surface of the first insulating layer 2 away from the circuit element, and the second insulating layer 5 is in direct contact with the surface of the first conductive portion 3 and the surface of the first insulating layer 2. By having the arrangement, the unevenness of the surface where the light-emitting element 4 is located can be prevented, so that the display color cast of the organic electroluminescent display substrate caused by the unevenness of the surface where the light-emitting element 4 is located is eliminated, and the display effect of the organic electroluminescent display substrate is greatly improved.

In the conventional organic electroluminescent display substrate, the thickness of the second insulating layer 5 needs to be designed to be thick to improve the flatness of the surface where the light-emitting device 4 is located. However, in the embodiments of the present disclosure, by filling the first conductive portion 3 in the groove 20 of the first insulating layer 2, under the condition that the thickness of the second insulating layer 5 is reduced compared with the conventional design thickness, the flatness of the surface where the light-emitting element 4 is located can be improved, so that the second insulating layer 5 can be made thin, which saves the material of the second insulating layer 5, saves the cost of the organic electroluminescent display substrate, and reduces the overall thickness of the organic electroluminescent display substrate.

In some embodiments, an orthographic projection of the first conductive portion 3 on the substrate 1 at least partially overlaps with an orthographic projection of the light-emitting element 4 on the substrate 1.

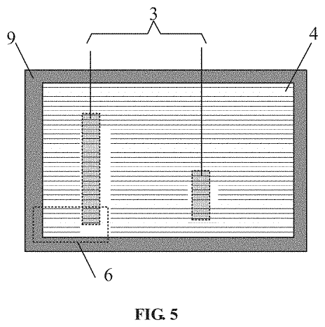

In some embodiments, referring to FIG. 4, the orthographic projection of the first conductive portion 3 on the substrate 1 falls within the orthographic projection of the light-emitting element 4 on the substrate 1. That is, the first conductive portion 3 covered by the light-emitting element 4 is completely filled in the groove 20 of the first insulating layer 2, so that the surface where the light-emitting element 4 is located is flat, thereby eliminating the display color cast of the organic electroluminescent display substrate caused by the unevenness of the surface where the light-emitting element 4 is located and improving the display effect of the organic electroluminescent display substrate. In the region other than the surface where the light-emitting device 4 is located, a conductive portion (not shown) partially embedded in the first insulating layer 2 may be disposed, which does not affect the flatness of the surface where the light-emitting device 4 is located.

In some embodiments, the circuit element includes a transistor 6 having a first electrode 62, a second electrode 63 and a control electrode 61, the groove 20 includes a first groove 21 and a second groove 22 separated from each other, the first conductive portion 3 includes a conductive electrode 31 at least partially filled in the first groove 21 and a conductive line 32 at least partially filled in the second groove 22, and the conductive electrode 31 is electrically coupled with the first electrode 62 and/or the second electrode 63 of the transistor 6 by a via hole in the first insulating layer 2.

In some embodiments, the conductive electrode 31 and the conductive line 32 are made of the same material and are disposed in a same layer. In the present disclosure, the term “in a same layer” refers to being formed using the same mask and/or in the same process. Since the conductive electrode 31 and the conductive line 32 in a same layer may cause unevenness of the surface where the light-emitting element 4 is located, the conductive electrode 31 and the conductive line 32 are completely filled in the groove of the first insulating layer 2, which can prevent the unevenness of the surface where the light-emitting element 4 is located, thereby eliminating the display color cast of the organic electroluminescent display substrate caused by the uneven surface where the light-emitting element 4 is located. In addition, the conductive electrode 31 and the conductive line 32 are used for display driving of the organic electroluminescent display substrate.

In some embodiments, an orthographic projection of the conductive line 32 on the substrate 1 at least partially overlaps with the orthographic projection of the light-emitting element 4 on the substrate 1.

In some embodiments, the orthographic projection of the conductive line 32 on the substrate 1 is within the orthographic projection of light-emitting element 4 on the substrate 1.

In some embodiments, in a cross-sectional view (e.g., the cross-sectional view shown in FIGS. 1-3) taken along a line perpendicular to an extending direction of the conductive line 32, the conductive electrode 31 and the conductive line 32 have different cross-sectional shapes. In other words, the conductive electrode 31 and the conductive line 32 are asymmetric. The asymmetry of the conductive electrode 31 and the conductive line 32 may cause the unevenness of the surface where the light-emitting element 4 is located, thereby causing a relatively serious problem of color cast in display. By filling the asymmetric conductive electrode 31 and the conductive line 32 in the groove of the first insulating layer 2, the display color cast of the organic electroluminescent display substrate caused by the unevenness of the surface where the light-emitting element 4 is located can be eliminated.

It should be noted that, the conductive electrode 31 and the conductive line 32 may he symmetrically arranged, but even in a case where the conductive electrode 31 and the conductive line 32 are symmetrically arranged, the surface where the light-emitting device 4 is located is not flat, which may cause the display color cast in display. By completely filling the conductive electrode 31 and the conductive line 32 in the groove of the first insulating layer 2, the display color cast of the organic electroluminescent display substrate caused by the unevenness of the surface where the light-emitting element 4 is located can be eliminated.

In some embodiments, at least a portion of the first conductive portion is electrically coupled to the light-emitting element 4 (e.g., an anode of the light-emitting element 4).

In some embodiments, the organic electroluminescent display substrate further includes a gate insulating layer 64 and an interlayer dielectric layer 8 sequentially stacked on the substrate 1. At least a portion of the control electrode 61 of the transistor 6 is disposed in the gate insulating layer 64, and each of the first electrode 62 and the second electrode 63 of the transistor 6 has a first portion passing through the gate insulating layer 64 and the interlayer dielectric layer 8 and a second portion on a surface (an upper surface of the interlayer dielectric layer 8 in the drawings) of the interlayer dielectric layer 8 away from the gate insulating layer 64, and the first insulating layer 2 is in direct contact with the surface of the interlayer dielectric layer 8 and the second portion of each of the first electrode 62 and the second electrode 63 of the transistor 6.

In some embodiments, the organic electroluminescent display substrate further includes a signal line 7 including at least a portion on a surface of the interlayer dielectric layer 8 away from the gate insulating layer 64, and the first insulating layer 2 is in direct contact with the signal line 7. The orthographic projection of the conductive line 32 on the substrate 1 at least partially overlaps with an orthographic projection of the signal line 7 on the substrate 1. The transistor 6 and the signal line 7 are disposed between the first insulating layer 2 and the substrate 1. The transistor 6 and the signal line 7 are used for display driving of the organic electroluminescence display substrate.

In some embodiments, the organic electroluminescent display substrate includes a plurality of conductive electrodes 31, a plurality of conductive lines 32, and a plurality of signal lines 7. The transistor 6 includes a gate electrode 61, a gate insulating layer 64, an active layer 65, a first electrode 62 and a second electrode 63, and the first electrode 62 is electrically coupled to the conductive electrode 31 provided correspondingly. The transistor 6 may have a top dual-gate structure, and accordingly, an interlayer dielectric layer 8 is further disposed between the gate electrode 61 and the first and second electrodes 62 and 63. The orthographic projection of the conductive line 32 on the substrate 1 at least partially overlaps with the orthographic projection of the signal line 7 on the substrate 1. A pixel defining layer 9 is further provided between adjacent light-emitting elements 4. The organic electroluminescent display substrate having the above structure is beneficial to reducing power consumption and improving display effect.

In some embodiments, the first insulating layer 2 and the second insulating layer 5 are organic material layers.

In another aspect, embodiments of the present disclosure further provide a method for fabricating the organic electroluminescent display substrate, including: forming a circuit element on a substrate; forming a first insulating layer on a side of the circuit element away from the substrate, the first insulating layer having at least one groove recessed from a surface of the first insulating layer away from the substrate and having a depth less than a thickness of the first insulating layer at a position where the at least one groove is located; forming a first conductive portion at least partially filling in the at least one groove and at least partially electrically coupled to the circuit element; forming a second insulating layer on a side of the first conductive portion away from the circuit element, the second insulating layer covering the first insulating layer and the first conductive portion; and forming a light-emitting element on a side of the second insulating layer away from the first conductive portion.

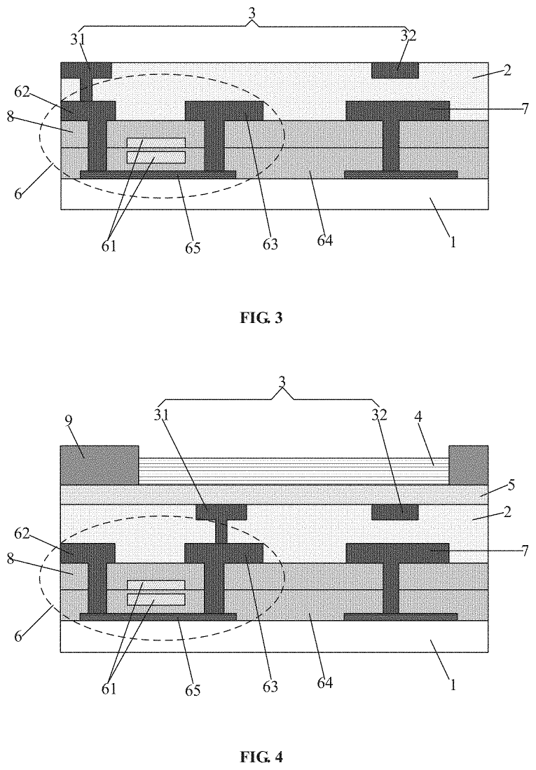

In some embodiments, the forming of the first insulating layer and the first conductive portion may refer to FIGS. 2-3. The forming of the first insulating layer may include: coating a first insulating layer film on the substrate 1; patterning the first insulating layer film using a half-tone exposure process to form the first insulating layer 2 having the at least one groove 20. The forming of the first conductive portion may include: filling the first conductive portion 3 in the groove 20.

Other structures of the organic electroluminescent display substrate are fabricated by conventional and mature processes, the details of which are not repeated herein.

According to the organic electroluminescence display substrate provided by the embodiments of the disclosure, the first conductive portion is filled in the groove of the first insulating layer, so that the unevenness of the surface where the light-emitting element is located can be alleviated or prevented, the display color cast of the organic electroluminescence display substrate caused by the unevenness of the surface where the light-emitting element is located is alleviated or eliminated, and the display effect of the organic electroluminescence display substrate is improved.

In another aspect, embodiments of the present disclosure provide a display device including the organic electroluminescent display substrate described above.

By adopting the organic electroluminescence display substrate, the display color cast caused by the unevenness of the surface where the light-emitting element is located can be alleviated or eliminated, and the display effect of the display device is improved.

The display device according to the present disclosure can be any product or component with a display function, such as an OLED panel, an OLED television, a display, a mobile phone, a navigator and the like.

It can be understood that the foregoing embodiments are merely exemplary embodiments used for describing the principle of the present disclosure, but the present disclosure is not limited thereto. It will be apparent to those skilled in the art that various changes and modifications can be made therein without departing from the spirit and scope of the disclosure, and these changes and modifications are to be considered within the scope of the disclosure.

What is claimed is:

1. An organic electroluminescent display substrate, comprising:
a substrate;
a circuit element on the substrate;
a first insulating layer on a side of the circuit element away from the substrate and having at least one groove recessed from a surface of the first insulating layer away from the substrate, the at least one groove having a depth less than a thickness of the first insulating layer at a position where the at least one groove is located;
a first conductive portion at least partially filled in the at least one groove and at least partially electrically coupled to the circuit element;
a second insulating layer on a side of the first conductive portion away from the circuit element and covering the first insulating layer and the first conductive portion; and
a light-emitting element on a side of the second insulating layer away from the first conductive portion.

2. The organic electroluminescent display substrate of claim 1, wherein a surface of the first conductive portion away from the circuit element is flush with a surface of the first insulating layer away from the circuit element, and the second insulating layer is in direct contact with the surface of the first conductive portion and the surface of the first insulating layer away from the circuit element.

3. The organic electroluminescent display substrate of claim 1, wherein the circuit element comprises a transistor having a first electrode, a second electrode, and a control electrode, the at least one groove comprises a first groove and a second groove separated from each other, the first conductive portion comprises a conductive electrode at least partially filled in the first groove and a conductive line at least partially filled in the second groove, and the conductive electrode is electrically coupled to at least one of the first electrode and the second electrode of the transistor through a via hole in the first insulating layer

4. The organic electroluminescent display substrate of claim 1, wherein an orthographic projection of the first conductive portion on the substrate at least partially overlaps with an orthographic projection of the light-emitting element on the substrate.

5. The organic electroluminescent display substrate of claim 4, wherein the orthogonal projection of the first conductive portion on the substrate falls within the orthogonal projection of the light-emitting element on the substrate.

6. The organic electroluminescent display substrate of claim 3, wherein an orthographic projection of the conductive line on the substrate at least partially overlaps with an orthographic projection of the light-emitting element on the substrate.

7. The organic electroluminescent display substrate of claim 6, wherein the orthographic projection of the conductive line on the substrate is within the orthographic projection of the light-emitting element on the substrate.

8. The organic electroluminescent display substrate of claim 3, further comprising: a gate insulating layer and an interlayer dielectric layer sequentially stacked on the substrate,
wherein at least a portion of the control electrode of the transistor is in the gate insulating layer, each of the first electrode and the second electrode of the transistor has a first portion penetrating through the gate insulating layer and the interlayer dielectric layer and a second portion on a surface of the interlayer dielectric layer away from the gate insulating layer, and the first insulating layer is in direct contact with the surface of the interlayer dielectric layer and the second portion of each of the first electrode and the second electrode of the transistor.

9. The organic electroluminescent display substrate of claim 8, further comprising: a signal line comprising at least a portion on the surface of the interlayer dielectric layer away from the gate insulating layer, the first insulating layer being in direct contact with the signal line.

10. The organic electroluminescent display substrate of claim 9, wherein an orthographic projection of the conductive line on the substrate at least partially overlaps with an orthographic projection of the signal line on the substrate.

11. The organic electroluminescent display substrate of claim 3, wherein the conductive electrode and the conductive line have a same material and are in a same layer.

12. The organic electroluminescent display substrate of claim 11, wherein in a cross-sectional view taken along a line perpendicular to an extending direction of the conductive line, the conductive electrode and the conductive line have different cross-sectional shapes.

13. The organic electroluminescent display substrate of claim 1. wherein the first insulating layer and the second insulating layer are organic material layers.

14. The organic electroluminescent display substrate of claim 1, wherein the first conductive portion is completely tilled in the at least one groove.

15. A display device, comprising the organic electroluminescent display substrate of claim 1.

16. A method for fabricating an organic electroluminescent display substrate, comprising:
forming a circuit element on a substrate;
forming a first insulating layer on a side of the circuit element away from the substrate, the first insulating layer having at least one groove recessed from a surface of the first insulating layer away from the substrate, and the at least one groove having a depth less than a thickness of the first insulating layer at a position where the at least one groove is located;
forming a first conductive portion at least partially filling in the at least one groove and at least partially electrically coupled to the circuit element;
forming a second insulating layer on a side of the first conductive portion away from the circuit element, the second insulating layer covering the first insulating layer and the first conductive portion; and
forming a light-emitting element on a side of the second insulating layer away from the first conductive portion.

17. The method of claim 16, wherein the forming of the first insulating layer comprises:
coating a first insulating layer film on the substrate; and
patterning the first insulating layer film using a half-tone exposure process to form the first insulating layer having the at least one groove.

18. The method of claim 16, wherein the forming of the first conductive portion comprises: filling the first conductive portion in the at least one groove.

19. The method of claim 16, wherein the first conductive portion is completely filled in the at least one groove.

20. The method of claim 16, wherein the circuit element comprises a transistor having a first electrode, a second electrode, and a control electrode, the at least one groove comprises a first groove and a second groove separated from each other, the first conductive portion comprises a conductive electrode at least partially filled in the first groove and a conductive line at least partially filled in the second groove, the conductive electrode is electrically coupled with at least one of the first electrode and the second electrode of the transistor through a via hole in the first insulating layer.
